(19) United States
(12) Patent Application Publication
(10) Pub. No.: US 2007/0176513 A1
(43) Pub. Date: Aug. 2, 2007

(54) Thin-film piezoelectric resonator and filter circuit

(75) Inventors: Ryoichi Ohara, Kanagawa-Ken (JP); Naoko Yanase, Kanagawa-Ken (JP); Kenya Sano, Kanagawa-Ken (JP); Takaaki Yasumoto, Kanagawa-Ken (JP); Kazuhiko Itaya, Kanagawa-Ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, TOKYO (JP)

(21) Appl. No.: 10/581,030

(22) PCT Filed: Mar. 8, 2006
(86) PCT No.: PCT/JP06/05070

§ 371 Date: Dec. 18, 2006

(30) Foreign Application Priority Data
Aug. 24, 2005 (JP) 2005-242660

(51) Int. Cl. H01L 41/09

(52) U.S. Cl. 310/324

(57) ABSTRACT

It is possible to provide a resonator structure that does not cause a variation in anti-resonant frequency can be achieved, even if the cavity and the upper and lower electrode shift. A thin-film piezoelectric resonator includes: a lower electrode provided on the principal surface of the substrate so as to cover the cavity; a piezoelectric film provided on the lower electrode so as to be located above the cavity; and an upper electrode. The upper electrode includes: a main portion which overlaps a part of the cavity, a protruding portion connected to the main portion, an extension portion provided at the opposite side of the main portion. The length of the protruding portion in a direction perpendicular to a direction of connecting to the main portion is substantially the same as the length of the connecting portion in a direction perpendicular to a direction of connecting to the main portion.

### CROSS-REFERENCE TO RELATED APPLICATION

This application is based upon and claims the benefit of priority from prior Japanese Patent Application No. 2005-242660 filed on Aug. 24, 2005 in Japan, the entire contents of which are incorporated herein by reference.

### BACKGROUND OF THE INVENTION

1. Field of the Invention

The present invention relates to a thin-film piezoelectric resonator and a filter circuit.

2. Related Art

As the wireless communication technology has rapidly developed and the transition to new systems is being achieved, there is an increasing demand for communication devices that are compatible with various transmission and reception systems. On top of that, the number of components in each communication device is rapidly increasing as mobile communication terminals have become advanced and sophisticated. Accordingly, the reduction in component size and the transition to module structures are becoming essential. Of the passive components of wireless circuits, filter circuits constitute a large proportion. Therefore, so as to reduce the circuit size and the number of components, filters need to be made smaller and to have module structures.

Examples of conventional filters include dielectric filters, SAW (Surface Acoustic Wave) filters, and LC filters. However, filters having film bulk acoustic resonators (thin-film piezoelectric resonators) are recently considered most suitable for small-sized module structures. Because the resonance phenomenon of piezoelectric oscillation is utilized in such filters, interference is not caused even if they are arranged close to each other, unlike with electromagnetic waves. Accordingly, compared with dielectric filters and LC filters, it is easier to make filters of this type smaller in size.

Also, as higher frequency bands are used for wireless communications than before, submicron processing is required for SAW filters that utilize surface acoustic waves, and therefore, it is difficult to manufacture SAW filters at low costs.

Meanwhile, as those filters having thin-film piezoelectric resonators utilize the longitudinal oscillation in the thickness direction of the piezoelectric films, higher frequency bands can be readily used as the operating bands by reducing the thickness of the piezoelectric films. Also, processing at 1-μm level is sufficient for the plane-direction processing (the film-direction processing). Accordingly, an increase in production cost as a result of using higher frequency bands can be avoided.

Furthermore, the substrates for thin-film piezoelectric resonators are not necessarily piezoelectric substrates, unlike those for SAW filters. Thin-film piezoelectric resonators can be formed on Si substrates or GaAs substrates that are semiconductors, and can constitute filters monolithically with LSI chips.

In such a thin-film piezoelectric resonator, the upper resonant portion and the lower resonant portion should be in contact with an air layer, so as to contain excited elastic vibration energy. Since there is a large difference in acoustic impedance between the air and the piezoelectric film and the electrode constituting the resonator of the thin-film piezoelectric resonator, the elastic vibration is efficiently reflected by the interface, and the elastic wave energy is contained in the resonant portions. To produce such a structure, it is necessary to form a cavity below the resonator. There are several ways to form the cavity. For example, a sacrifice layer is embedded beforehand in the substrate, and is removed by etching after the formation of the upper and lower electrodes and the piezoelectric film. Alternatively, after the resonator is formed on the substrate, the substrate is removed by etching that is performed on the bottom surface of the substrate (disclosed in “Appl. Phys. Lett. 43(8) P750, K. M. Lakin”, for example).

The hollow structure having such a cavity is poor in mechanical strength. Therefore, the lower electrode may be designed to be larger than the cavity so that a step is not formed with the lower electrode in the hollow structure (as disclosed in “Appl. Phys. Lett. 43(8) P750, K. M. Lakin”, for example).

By this method, however, the upper and lower electrodes face each other outside the cavity, and the facing portion serves as a parasitic capacitance. Because of this, the effective electromechanical coupling coefficient (piezoelectric characteristics) of the piezoelectric resonator becomes lower. As a result, the anti-resonant frequency becomes lower. Especially, in a case where the cavity is formed by etching the bottom surface of the substrate, a variation in anti-resonant frequency is caused by a difference in location between the cavity pattern and the electrode pattern, a difference in the shape of the etched cavity, or a variation in the etching process. The variation in anti-resonant frequency does not only cause a shift of the band of a bandpass filter formed with the piezoelectric resonators, but also affect the shape of the filter in the neighborhood of the center frequency.

### SUMMARY OF THE INVENTION

The present invention is proposed in consideration of the aforementioned circumstances, and it is an object of the present invention to provide a thin-film piezoelectric resonator and a filter circuit that has such a resonator structure as not to cause a variation in anti-resonant frequency even if a difference in location is caused between the cavity and the upper and lower electrodes due to a variation in the manufacturing process.

A thin-film piezoelectric resonator according to a first aspect of the present invention includes: a substrate having a cavity which penetrates through from the principal surface to the bottom surface thereof; a lower electrode provided on the principal surface of the substrate so as to cover the cavity; a piezoelectric film provided on the lower electrode so as to be located above the cavity; and an upper provided on the piezoelectric film, including; a main portion which overlaps a part of the cavity in a plan view, a protruding portion, which is connected to the main portion, a part of which overlaps the cavity and the remaining part thereof does not overlap the cavity but overlaps the lower electrode, an extension portion provided at the opposite side of the main portion from the protruding portion, and a connecting portion, which connects the main portion and the extension portion, provided so that at least a part thereof does not overlap the cavity but overlaps the lower electrode, the length of the protruding portion in a direction perpendicular to a direction of connecting to the main portion being substantially the same as the length of the connecting portion in a direction perpendicular to a direction of connecting to the main portion.

The remaining part of the protruding portion and the part of the connecting portion can be placed symmetrically with respect to a center line of the cavity.

The remaining part of the protruding portion and the part of the connecting portion can be placed asymmetrically with respect to a center line of the cavity.

The length of the protruding portion in a direction perpendicular to a direction of connecting to the main portion can be smaller than the length of the main portion in a direction perpendicular to a direction of connecting to the protruding portion.

A thin-film piezoelectric resonator according to a second aspect of the present invention: a substrate having a cavity which penetrates through from the principal surface to the bottom surface thereof; a lower electrode provided on the principal surface of the substrate so as to cover the cavity; a piezoelectric film provided on the lower electrode so as to be located above the cavity; and an upper electrode provided on the piezoelectric film, including; a main portion which overlaps a part of the cavity, a first portion provided so as to connect to one of sides of the main portion, a second portion provided so as to connect to the other one of the sides of the main portion, and a link portion linking the first portion and the second portion, the link portion not overlapping the lower electrode in a plan view, the length of the first portion in a direction perpendicular to a direction of connecting to the main portion being substantially the same as the length of the second portion in a direction perpendicular to a direction of connecting to the main portion.

The first portion and the second portion of the upper electrode can be placed symmetrically with respect to a center line of the cavity.

The first portion and the second portion of the upper electrode can be placed asymmetrically with respect to a center line of the cavity.

The length of the first portion of the upper electrode in a direction perpendicular to a direction of connecting to the main portion can be smaller than the length of the main portion in the perpendicular direction.

A filter circuit according to a third aspect of the present invention includes the thin-film piezoelectric resonator as described in any one of the first and second aspects.

The remaining part of the protruding portion and the part of the connecting portion of the thin-film piezoelectric resonator can be placed symmetrically with respect to a center line of the cavity.

The remaining part of the protruding portion and the part of the connecting portion of the thin-film piezoelectric resonator can be placed asymmetrically with respect to a center line of the cavity.

The length of the protruding portion in a direction perpendicular to a direction of connecting to the main portion of the thin-film piezoelectric resonator can be smaller than the length of the main portion in a direction perpendicular to a direction of connecting to the protruding portion.

### BRIEF DESCRIPTION OF THE DRAWINGS

FIG. 1 is a plan view of a thin-film piezoelectric resonator in accordance with a first embodiment of the present invention;

FIG. 2 is a cross-sectional view of the thin-film piezoelectric resonator of the first embodiment, taken along the line A-A of FIG. 1;

FIG. 3 is a plan view of a thin-film piezoelectric resonator in accordance with a modification of the first embodiment;

FIG. 4 is a plan view of a thin-film piezoelectric resonator in accordance with a comparative example of the first embodiment;

FIG. 5 is a plan view of a filter circuit in accordance with a second embodiment of the present invention; and

FIG. 6 is an equivalent circuit of the filter circuit of the second embodiment.

### DETAILED DESCRIPTION OF THE INVENTION

Before a description of embodiments of the present invention, the principles of the present invention are explained. The inventors studied resonator structures that are not much affected by variations in characteristics during manufacturing processes. As a result, the inventors found that variations in the cavity shape greatly affect the resonator characteristics and the pass characteristics of a filter that is formed with resonators. Such variations in the cavity shape are caused during the process of forming cavities using sacrifice layers, and are more problematic in the process of forming cavities by etching each bottom surface. The variations in the cavity shape can be divided into two types: variations in the cavity size; and variations in the cavity location. The latter one has more adverse influence. So as to eliminate the undesired influence, the inventors made an intensive study on electrodes and the two-dimensional shapes of cavities, and found that the problem can be solved by a structure in which the total sum of the parasitic capacitances in the upper and lower electrodes facing each other outside the cavity does not vary with a shift of the cavity location.

The following is a description of embodiments of the present invention, with reference to the accompanying drawings.

### FIRST EMBODIMENT

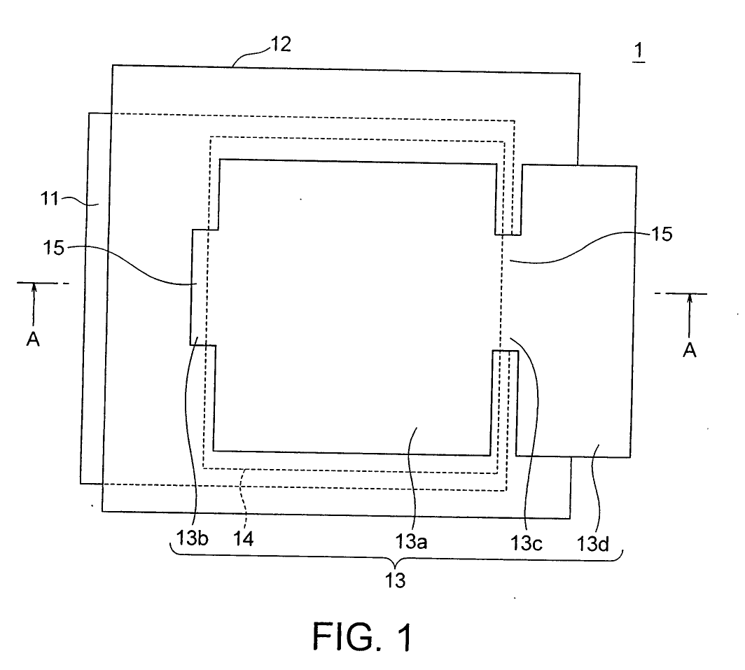

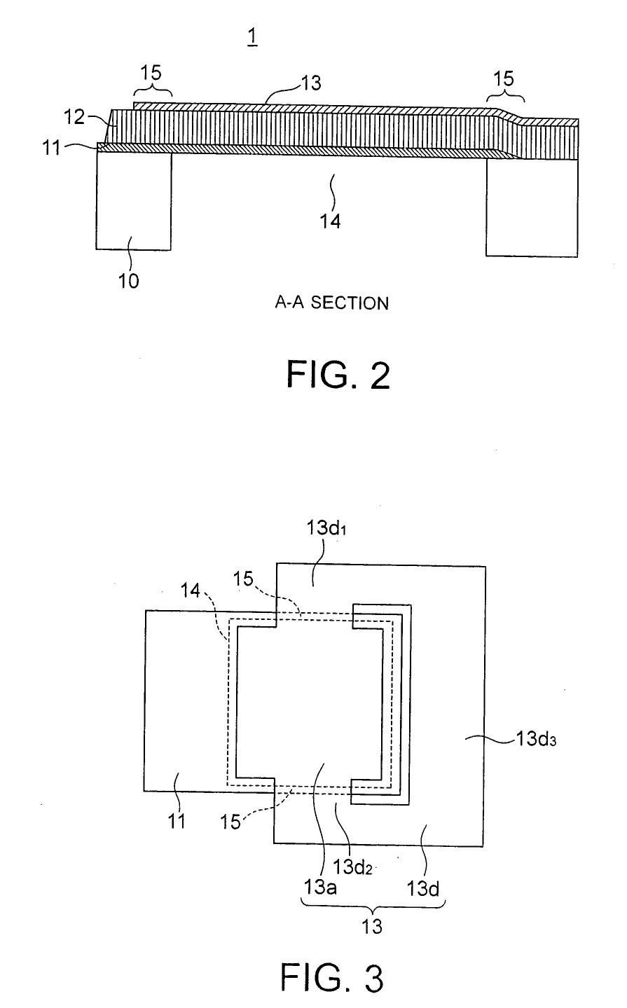

FIGS. 1 and 2 illustrate a thin-film piezoelectric resonator in accordance with a first embodiment of the present invention. FIG. 1 is a plan view of the thin-film piezoelectric resonator 1 of this embodiment, and FIG. 2 is a cross-sectional view of the thin-film piezoelectric resonator, taken along the line A-A of FIG. 1.

The thin-film piezoelectric resonator 1 of this embodiment includes a lower electrode 11 that is formed on a substrate 10, a piezoelectric film 12 that is formed on the lower electrode 11, an upper electrode 13 that is formed on the piezoelectric film 12, and a cavity (an opening) 14 that is formed in the substrate 10 and is in contact with the surface of the lower electrode 11 opposite from the piezoelectric film 12.

The lower electrode 11 covers the cavity 14. The piezoelectric film 12 covers most of the lower electrode 11. The upper electrode 13 has a main portion 13a, a protruding portion 13b, a connecting portion 13c, and an extension portion 13d. The main portion 13a is designed to be located immediately above the cavity 14, and the entire main portion 13a overlaps part of the cavity 14. The protruding portion 13b is provided on the opposite side of the main portion 13a from the connecting portion 13c. Part of the protruding portion 13b overlaps the cavity 14, and the rest of the protruding portion 13b overlaps the lower electrode 11. Accordingly, the rest of the protruding portion 13b serves as a parasitic capacitance 15.

The connecting portion 13c connects the main portion 13a and the extension portion 13d. Part of the connecting portion 13c overlaps the cavity 14, and part of the rest of the connecting portion 13c overlaps the lower electrode 11. Accordingly, the part of the rest of the connecting portion 13c serves as a parasitic capacitance 15. In this embodiment, the protruding portion 13b and the connecting portion 13c have the same widths (the length in the vertical direction in FIG. 1), and are placed symmetrically. The width of each of the protruding portion 13b and the connecting portion 13c is smaller than the width of the main portion 13a. The extension portion 13d is placed so as not to overlap the cavity 14, and has substantially the same width as the main portion 13a.

The thin-film piezoelectric resonator 1 of this embodiment is manufactured in the following manner. First, a thermal oxide film (not shown) is formed on the substrate 10 made of Si. A lower electrode material film that is made of A1 or the like is then formed by a sputtering operation, and patterning is performed by chlorine-based RIE (Reactive Ion Etching), so as to form the lower electrode 11. Here, the processing conditions are controlled so that the end faces of the lower electrode 11 are tapered. The piezoelectric film 12 made of AIN is then formed also by a sputtering operation, and is processed by chlorine-based RIE. An upper electrode film that is made of Mo or the like is then formed and is patterned, so as to form the upper electrode 13. Lastly, dry etching or wet etching is performed on the bottom face of the substrate 10, so as to form the cavity (opening) 14.

Since the thin-film piezoelectric resonator 1 of this embodiment has the parasitic capacitances 15 placed symmetrically as shown in FIG. 1, the total sum of the parasitic capacitances 15 does not vary even if the location of the cavity 14 shifts from side to side. Accordingly, the anti-resonant frequency does not vary.

Also, since there are no parasitic capacitances in the upper and lower regions in FIG. 1, the cavity 14 shifting up and down does not affect the parasitic capacitances 15. The largest possible positional difference that may be caused during the manufacturing process is normally 15 μm for a 2 GHz resonator, and the possibility of having a positional difference larger than that is very low. Accordingly, if the length of the connecting portion 13c of the upper electrode 13 (the size of the connecting portion 13c in the horizontal direction in FIG. 1) is larger than the length of the protruding portion 13b by 15 μm, the cavity 14 shifting side to side during the manufacturing process does not change the total sum of the parasitic capacitances. Here, the length of the protruding portion 13b should be 15 μm or larger.

Although the width of the extension portion 13d is larger than the width of the connecting portion 13c in this embodiment, it may be the same as the width of the connecting portion 13c.

Also, the parasitic capacitances 15 are placed on the right and left sides of the main portion 13a in FIG. 1. However, as in a modification shown in FIG. 3, the parasitic capacitances 15 may be placed on the top and bottom sides of the main portion 13a. In such a case, the extension portion 13d is formed with a ring-like structure having a notch, and the main portion 13a is located at the notch portion. The extension portion 13d connects directly to the main portion 13a. The extension portion 13d has a first portion 13d₁, that extends in parallel with the lower electrode 11 in the longitudinal direction and is designed to connect to one side of the main portion 13a, a second portion 13d₂ that is designed to connect to the other side of the main portion 13a, and a link portion 13d₃ that links the first portion 13d₁ and the second portion 13d₂ and does not overlap the lower electrode 11 in the plan view. The “longitudinal direction” of the lower electrode 11 is the direction extending between the portion of the lower electrode 11 overlapping the cavity 14 and the portion of the lower electrode 11 connected to an external power source (in FIG. 3, the left-side portion of the portion overlapping the cavity 14), which is the horizontal direction in FIG. 3. In general, the length of the lower electrode 11 in the longitudinal direction is larger than the length of the lower electrode 11 in a direction perpendicular to the longitudinal direction. The size (the width) of the first portion 13d₁ in a direction perpendicular to the direction of connecting to the main portion 13a is substantially the same as the size (the width) of the second portion 13d₂ in a direction perpendicular to the direction of connecting to the main portion 13a. The size of each of the first and second portions 13d₁ and 13d₂ of the upper electrode 13a in the direction of connecting to the main portion 13a is preferably 15 μm or larger. In this manner, the total sum of the parasitic capacitances 15 can be made invariable, even if the location of the cavity 14 shifts in the vertical direction during the manufacturing process in FIG. 3. Thus, a variation in anti-resonant frequency can be prevented.

Unlike in the first embodiment illustrated in FIG. 1, the main portion 13a connects directly to the extension portion 13d, and a connecting portion narrower than the main portion 13a is not employed in this modification. Accordingly, the series resistance is lower and the resonant Q value is larger than in the first embodiment illustrated in FIG. 1. However, the first embodiment illustrated in FIG. 1 has the advantage of being smaller in size than the modification illustrated in FIG. 3.

In the first embodiment and the modification described above, the two parasitic capacitances 15 are placed symmetrically about a center line of the main portion 13a. However, the two parasitic capacitances 15 may be placed asymmetrically.

So as not to vary the total sum of parasitic capacitances, at least one of the protruding portion 13b and the connecting portion 13c may be divided into a few parts in the first embodiment. In the modification, at least one of the first and second portions 13d₁ and 13d₂ may be divided into a few parts.

### COMPARATIVE EXAMPLE

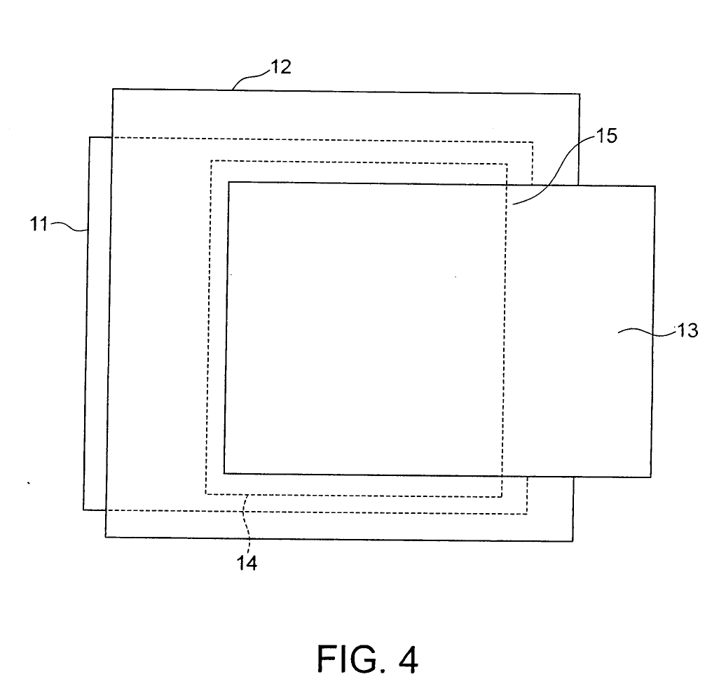

FIG. 4 is a plan view of a comparative example of this embodiment. In this comparative example, the protruding portion 13b and the connecting portion 13c are removed from the structure of the first embodiment shown in FIG. 1, and the main portion 13a and the extension portion 13d are integrated to form the upper electrode 13. Since the parasitic capacitance 15 exists only on the right side of the cavity 14, the size of the parasitic capacitance 15 does not vary when the cavity shifts in the vertical direction of the cavity 14. However, when the cavity 14 shifts side to side, the size of the parasitic capacitance 15 varies, resulting in a variation in anti-resonant frequency.

As described so far, in this embodiment, the total sum of parasitic capacitances is invariable, even if the cavity and the upper and lower electrode shift during the manufacturing process. Thus, the anti-resonant frequency does not vary.

In this embodiment, each of electrodes has a quadrangular shape such as a rectangular shape or a square shape. The shape of each of electrodes is not limited to the quadrangular shape, but may be a circular shape, an elliptic shape, or a shape surrounded with a smooth closed curve.

### SECOND EMBODIMENT

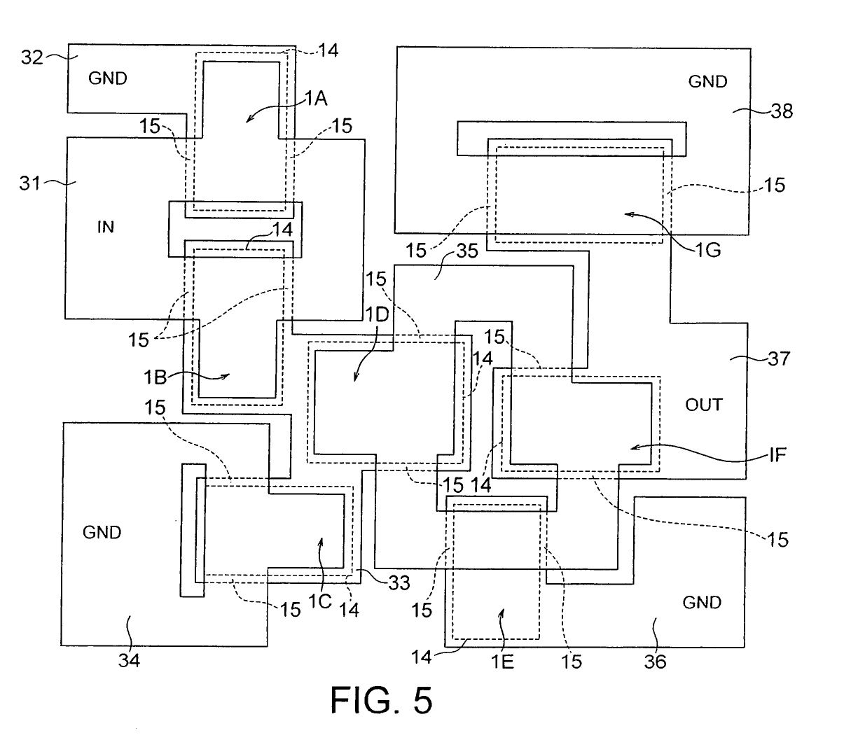

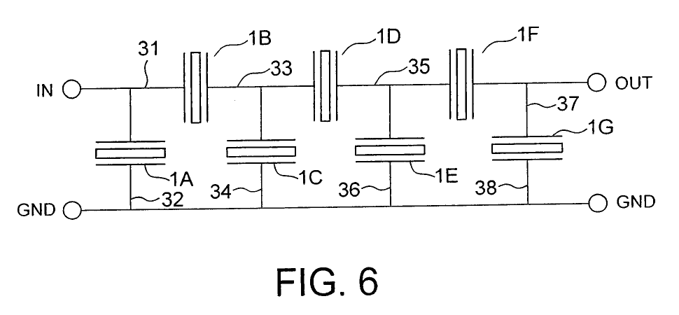

Referring now to FIGS. 5 and 6, a filter circuit in accordance with a second embodiment of the present invention is described. FIG. 5 is a plan view of the filter circuit in accordance with this embodiment, and FIG. 6 is an equivalent circuit of the filter circuit in accordance with this embodiment.

The filter circuit of this embodiment includes seven thin-film piezoelectric resonators 1A through 1G. The three thin-film piezoelectric resonators 1B, 1D, and 1F are connected in series, and the four thin-film piezoelectric resonators lA, iC, 1E, and 1G are connected in parallel. The filter circuit of this embodiment is a ladder bandpass filter circuit. Each of the thin-film piezoelectric resonators 1A through 1G is a thin-film piezoelectric resonator in accordance with the first embodiment or the modification of the first embodiment.

Either the upper electrode or the lower electrode (in this example, the upper electrode) of the thin-film piezoelectric resonator 1A is an electrode 31 to which an input signal IN is to be input, and the other one (in this example, the lower electrode) is an electrode 32 that is connected to a ground potential GND. The parasitic capacitances 15 of the thin-film piezoelectric resonator 1A are placed symmetrically.

Either the upper electrode or the lower electrode (in this example, the upper electrode) of the thin-film piezoelectric resonator 1B is the electrode 31, and the other one (in this example, the lower electrode) is an electrode 33. The parasitic capacitances 15 of the thin-film piezoelectric resonator 1B are placed symmetrically. Here, the thin-film piezoelectric resonators 1A and 1B share the electrode 31 as the upper electrode.

Either the upper electrode or the lower electrode (in this example, the lower electrode) of the thin-film piezoelectric resonator 1C is the electrode 33, and the other one (in this example, the upper electrode) is an electrode 34 that is connected to a ground potential GND. The parasitic capacitances 15 of the thin-film piezoelectric resonator iC are placed symmetrically.

Either the upper electrode or the lower electrode (in this example, the lower electrode) of the thin-film piezoelectric resonator 1C is the electrode 33, and the other one (in this example, the upper electrode) is an electrode 35. The parasitic capacitances 15 of the thin-film piezoelectric resonator 1C are placed asymmetrically. The thin-film piezoelectric resonators 1B, 1C, and 1D share the electrode 33 as the lower electrode.

Either the upper electrode or the lower electrode (in this example, the upper electrode) of the thin-film piezoelectric resonator 1E is the electrode 35, and the other one (in this example, the lower electrode) is an electrode 36 that is connected to a ground potential GND. The parasitic capacitances 15 of the thin-film piezoelectric resonator 1E are placed symmetrically.

Either the upper electrode or the lower electrode (in this example, the upper electrode) of the thin-film piezoelectric resonator 1F is the electrode 35, and the other one (in this example, the lower electrode) is an electrode 37 from which an output signal OUT is to be output. The parasitic capacitances 15 of the thin-film piezoelectric resonator IF are placed asymmetrically. The thin-film piezoelectric resonators 1D, 1E, and 1F share the electrode 35 as the upper electrode.

Either the upper electrode or the lower electrode (in this example, the lower electrode) of the thin-film piezoelectric resonator 1G is the electrode 37, and the other one (in this example, the upper electrode) is an electrode 38 that is connected to a ground potential GND. The parasitic capacitances 15 of the thin-film piezoelectric resonator 1G are placed symmetrically. The thin-film piezoelectric resonators 1F and 1G share the electrode 37 as the lower electrode.

In the filter circuit of this embodiment having the above structure, each of the thin-film piezoelectric resonators is a thin-film piezoelectric resonator of the first embodiment or the modification of the first embodiment. Accordingly, even if the cavity and the upper and lower electrodes shift due to a variation in the manufacturing process, the total sum of the parasitic capacitances is invariable. Thus, the anti-resonant frequency does not vary.

As described so far, according to the present invention, a resonator structure that does not cause a variation in anti-resonant frequency can be achieved, even if the cavity and the upper and lower electrode shift.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A thin-film piezoelectric resonator comprising:
a substrate having a cavity which penetrates through from the principal surface to the bottom surface thereof;
a lower electrode provided on the principal surface of the substrate so as to cover the cavity;
a piezoelectric film provided on the lower electrode so as to be located above the cavity; and
an upper electrode provided on the piezoelectric film, including;
a main portion which overlaps a part of the cavity in a plan view,
a protruding portion, which is connected to the main portion, a part of which overlaps the cavity and the remaining part thereof does not overlap the cavity but overlaps the lower electrode,
an extension portion provided at the opposite side of the main portion from the protruding portion, and
a connecting portion, which connects the main portion and the extension portion, provided so that at least a part thereof does not overlap the cavity but overlaps the lower electrode,
the length of the protruding portion in a direction perpendicular to a direction of connecting to the main portion being substantially the same as the length of the connecting portion in a direction perpendicular to a direction of connecting to the main portion.

2. The thin-film piezoelectric resonator as claimed in claim 1, wherein the remaining part of the protruding portion and the part of the connecting portion are placed symmetrically with respect to a center line of the cavity.

3. The thin-film piezoelectric resonator as claimed in claim 1, wherein the remaining part of the protruding portion and the part of the connecting portion are placed asymmetrically with respect to a center line of the cavity.

4. The thin-film piezoelectric resonator as claimed in claim 1, wherein the length of the protruding portion in a direction perpendicular to a direction of connecting to the main portion is smaller than the length of the main portion in a direction perpendicular to a direction of connecting to the protruding portion.

5. A thin-film piezoelectric resonator comprising:
a substrate having a cavity which penetrates through from the principal surface to the bottom surface thereof;
a lower electrode provided on the principal surface of the substrate so as to cover the cavity;
a piezoelectric film provided on the lower electrode so as to be located above the cavity; and
an upper electrode provided on the piezoelectric film, including;
a main portion which overlaps a part of the cavity,
a first portion provided so as to connect to one of sides of the main portion,
a second portion provided so as to connect to the other one of the sides of the main portion, and
a link portion linking the first portion and the second portion, the link portion not overlapping the lower electrode in a plan view,
the length of the first portion in a direction perpendicular to a direction of connecting to the main portion being substantially the same as the length of the second portion in a direction perpendicular to a direction of connecting to the main portion.

6. The thin-film piezoelectric resonator as claimed in claim 5, wherein the first portion and the second portion of the upper electrode are placed symmetrically with respect to a center line of the cavity.

7. The thin-film piezoelectric resonator as claimed in claim 5, wherein the first portion and the second portion of the upper electrode are placed asymmetrically with respect to a center line of the cavity.

8. The thin-film piezoelectric resonator as claimed in claim 5, wherein the length of the first portion of the upper electrode in a direction perpendicular to a direction of connecting to the main portion is smaller than the length of the main portion in the perpendicular direction.

9. A filter circuit comprising the thin-film piezoelectric resonator as claimed in claim 1.

10. The filter circuit as claimed in claim. 9, wherein the remaining part of the protruding portion and the part of the connecting portion of the thin-film piezoelectric resonator are placed symmetrically with respect to a center line of the cavity.

11. The filter circuit as claimed in claim 9, wherein the remaining part of the protruding portion and the part of the connecting portion of the thin-film piezoelectric resonator are placed asymmetrically with respect to a center line of the cavity.

12. The filter circuit as claimed in claim 9, wherein the length of the protruding portion in a direction perpendicular to a direction of connecting to the main portion of the thin-film piezoelectric resonator is smaller than the length of the main portion in a direction perpendicular to a direction of connecting to the protruding portion.

13. A filter circuit comprising the thin-film piezoelectric resonator as claimed in claim 5.

14. The filter circuit as claimed in claim 13, wherein the first portion and the second portion of the upper electrode of the thin-film piezoelectric resonator are placed symmetrically with respect to a center line of the cavity.

15. The filter circuit as claimed in claim 13, wherein the first portion and the second portion of the upper electrode of the thin-film piezoelectric resonator are placed asymmetrically with respect to a center line of the cavity.

16. The filter circuit as claimed in claim 13, wherein the length of the first portion of the upper electrode in a direction perpendicular to a direction of connecting to the main portion of the thin-film piezoelectric resonator is smaller than the length of the main portion in the perpendicular direction.
